(19) United States
(12) Patent Application Publication
(10) Pub. No.: US 2021/0365139 A1
(43) Pub. Date: Nov. 25, 2021

(54) TOUCH DISPLAY PANEL AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Weimeng ZHANG, Beijing (CN); Qian WANG, Beijing (CN)

(21) Appl. No.: 16/612,471

(22) PCT Filed: Jan. 16, 2019
(86) PCT No.: PCT/CN2019/072011

§ 371 Date: Nov. 11, 2019

(30) Foreign Application Priority Data
May 29, 2018 (CN) 201820816495.9

(51) Int. Cl. G06F 3/041; H01L 27/32; G02F 1/1362; G06F 3/044

(52) U.S. Cl. CPC G06F 3/0412; H01L 27/3276; G06F 3/044; H01L 27/323; G06F 3/04166; G02F 1/136286

(57) ABSTRACT

A touch display panel and a display device are provided. The touch display panel includes a touch integrated circuit (IC) and a base substrate; the base substrate is provided with data lines extending in a X1 direction, gate lines extending in a X2 direction intersected with the X1 direction, at least one touch line, and a plurality of touch capacitors arranged in the X2 direction and the X1 direction each touch capacitor is connected with one of the touch line, and the touch IC is connected with each touch line; the base substrate has a plurality of touch regions arranged along the X1 direction sequentially, and each touch region is provided with at least one gate line and at least one row of touch capacitors; each touch line is connected in series with at least one switching unit, which is connected with at least one gate line in one-to-one correspondence.

### CROSS-REFERENCE OF RELATED APPLICATION

The present application claims priority of China Patent application No. 201820816495.9 filed on May 29, 2018 under the title of “TOUCH DISPLAY PANEL AND DISPLAY DEVICE”, the content of which is incorporated in its entirety as portion of the present application by reference herein.

### TECHNICAL FIELD

At least one embodiment of the present disclosure relates to a touch display panel and a display device.

### BACKGROUND

With the development of display technologies, touch display panels have been widely applied in electronic products such as mobile phones, smart watches and tablet computers, gradually.

The touch display panel is generally formed by bonding a display panel with a touch panel. The touch display panel possesses both of a display function and a touch function. During an operation of the touch display panel, it needs to periodically perform a touch display scanning operation; and during every touch display scanning period, the touch display panel usually performs a display scanning operation and a touch scanning operation sequentially.

### SUMMARY

On one aspect, an embodiment of the present disclosure provides a touch display panel including a touch integrated circuit (IC) and a base substrate; the base substrate is provided with data lines extending in a X1 direction, gate lines extending in a X2 direction intersected with the X1 direction, at least one touch line, and a plurality of touch capacitors, the plurality of touch capacitors are arranged in the X2 direction as a row direction and arranged in the X1 direciton as a column direction, each of the plurality of touch capacitors is connected with one of the at least one touch line, and the touch IC is connected with each of the at least one touch line;

the base substrate has a plurality of touch regions arranged along the X1 direction sequentially, and each of the plurality of touch regions is provided with at least one gate line and at least one row of touch capacitors;

each of the at least one couch line is connected in series with at least one switching unit, and the at least one switching unit is connected with at least one gate line on the base substrate in one-to-one correspondence;

the switching unit is configured to be switched off in the case where a display scanning operation is performed on a corresponding gate line connected to the switching unit, and to be switched on in the case where the display scanning operation is not performed on the corresponding gate line connected to the switching unit; and

the touch IC is configured to apply a touch scanning signal to the touch line connected to the at least one row of touch capacitors in any touch region of the plurality of touch regions upon the display scanning operation on the at least one gate line in the any touch region being completed, so as to perform a touch scanning operation on the at least one row of touch capacitors in the any touch region.

Optionally, the switching unit includes a P-type field effect transistor (PI-BT), the PFET is connected to the corresponding gate line through a gate electrode of the PFET, and the PFET is connected in series with the corresponding touch line through a source electrode and a drain electrode of the PFET.

Optionally, the base substrate is further provided with at least one sense line arranged to be intersected with the at least one touch line, the touch line is parallel to the data line, and the sense line is parallel to the gate line;

each of the at least one touch line is connected with one end of one corresponding touch capacitor on the base substrate, each of the at least one sense line is connected with the other end of the one corresponding touch capacitor on the base substrate;

each of the plurality of touch regions is provided with one sense line, and a portion of each of the at least one sense line located in each of the plurality of touch regions is connected in series with at least one switching unit, and the at least one switching unit is connected with the at least one gate line in each of the plurality of touch regions in one-to-one correspondence; and

the touch IC is configured to, upon the display scanning operation performed on the at least one gate line in any touch region of the plurality of touch regions being completed, when a touch scanning signal is applied to the touch line connected to the at least one row of touch capacitors in the any touch region, sense the touch scanning signal through the sense line in the any touch region so as to perform a touch scanning operation on the at least one row of touch capacitors in the any touch region.

Optionally, in any of the plurality of touch regions, the at least one switching unit is located between the touch IC and the at least one row of touch capacitors.

Optionally, the at least one touch line is connected with the plurality of touch capacitors in one-to-one correspondence, and

the at least one switching unit connected in series with each of the at least one touch line is located in a same touch region and is connected with the at least one gate line in the same touch region in one-to-one correspondence.

Optionally, the base substrate further has at least one first region arranged along the X1 direction sequentially, and

the first region is located between adjacent two touch regions, and the first region is provided with at least one gate line and is not provided with the touch capacitor.

Optionally, between any two adjacent touch regions, one first region is provided.

Optionally, each of the plurality of touch regions includes a plurality of second regions and at least one third region,

in each of the plurality of touch regions, the plurality of second regions are arranged along the X2 direction sequentially, and the third region is located between adjacent two second regions; and

both of the second region and the third region are provided with at least one data line, the second region is provided with at least one touch line, and the third region is not provided with the touch line.

Optionally, between any two adjacent second regions, one third region is provided.

Optionally, the base substrate is further provided with a plurality of gate driver on array (GOA) units connected with the gate lines in one-to-one correspondence, and the plurality of GOA units are cascaded to constitute a GOA.

Optionally, the touch display panel is a built-in touch display panel, an on-cell touch display panel or an integrated touch display panel.

Optionally, the touch display panel is a liquid crystal touch display panel, an organic light-emitting diode (OLED) touch display panel or an active matrix organic light-emitting diode (AMOLED) touch display panel.

Optionally, the touch display panel has a display region of 10.1 inches, and a length of each of the at least one first region in the X1 direction is 0.1 mm

On the other aspect, it provides a display device including any one of the above-described touch display panels.

### BRIEF DESCRIPTION OF THE DRAWINGS

In order to clearly illustrate the technical solutions of the embodiments of the present disclosure, the drawings that are necessary for a description of the embodiments will be briefly described in the following. Apparently, the described drawings merely are related to a part of embodiments of the present disclosure. Based on these drawings, other drawing(s) may be obtained by those ordinary skilled in the art without any creative labors.

FIG. 1 is a schematic diagram illustrating a structure of a touch display panel provided by an embodiment of the present disclosure;

FIG. 2 is a schematic diagram illustrating a structure of a part of any touch region in a touch display panel provided by an embodiment of the present disclosure;

FIG. 3 is a schematic diagram illustrating a structure of a part of any touch region in another touch display panel provided by an embodiment of the present disclosure;

FIG. 4 is a schematic diagram illustrating a structure of another touch display panel provided by an embodiment of the present disclosure;

FIG. 5 is a schematic diagram illustrating a touch scanning operation and a display scanning operation of a touch display panel in the related art; and

FIG. 6 is a schematic diagram illustrating a touch scanning operation and a display scanning operation of a touch display panel provided by an embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

The touch display panel has been preferred by mobile display terminal manufactures for its advantages such as unique function and economic efficiency. Furthermore, with the development of science and technology, people have higher and higher requirements on the touch display panel. For example, it not only requires the touch display panel to have higher resolution but also to achieve better touch effect. An embodiment of the present disclosure provides a touch display panel and a display device, which can achieve better touch effect for both of higher resolution and lower resolution.

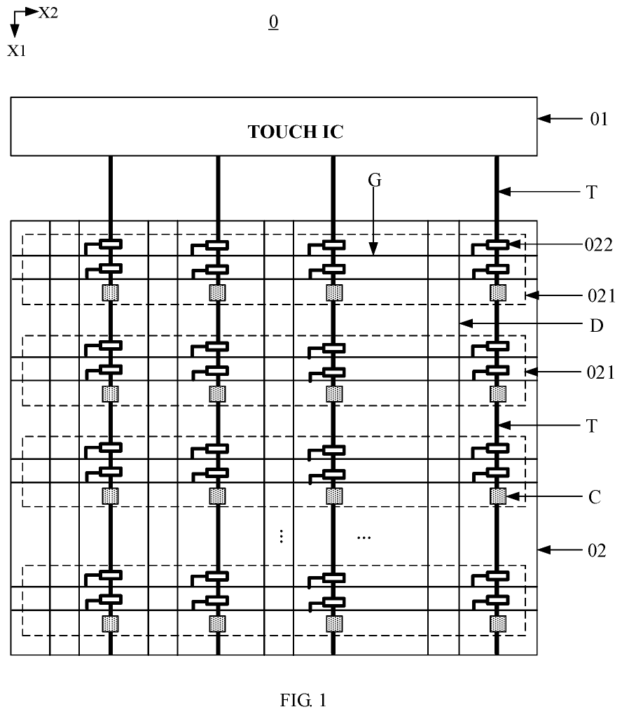

FIG. 1 is a schematic diagram illustrating a structure of a touch display panel provided by an embodiment of the present disclosure. As illustrated in FIG. 1, a touch display panel 0 may include a touch integrated circuit (IC) 01 and a base substrate 02.

By way of example, the base substrate 02 is provided with a plurality of data lines D extending along a X1 direction, a plurality of gate lines G extending along a X2 direction perpendicular to the X1 direction, a plurality of touch lines T extending along the X1 direction, and a plurality of touch capacitors C arranged in rows and columns (e.g., by taking the X1 direction as the column direction and taking the X2 direction as the row direction); each of the touch capacitors C is connected with one of the touch lines T, and the touch IC 01 is connected with all of the touch lines T.

Still referring to FIG. 1, the base substrate 02 may be divided into a plurality of touch regions 021 arranged along the X1 direction sequentially, and each of the touch regions 021 is provided with at least one gate line G and at least one row of touch capacitors C. FIG. 1 illustrates the case where each of the touch regions 021 of the base substrate 02 is provided with two gate lines G and one row of touch capacitors C, by way of example. Optionally, each of the touch regions 021 may also be provided with other numbers (e.g., ten) of gates lines G and other numbers (e.g., two) of rows of capacitors C, without particularly limited in the embedment of the present disclosure.

Still referring to FIG. 1, each of the couch lines T may be connected in series with at least one switching unit 022, and the at least one switching unit 022 is connected with at least one gate line G on the base substrate 02 in one-to-one correspondence; the switching unit 022 is configured to be switched off in the case where a display scanning operation is performed on a corresponding gate line connected to the switching unit, and to be switched on in the case where the display scanning operation is not performed on the corresponding gate line connected to the switching unit.

According to the embodiment of the present disclosure, because each of the touch regions 021 is provided with a gate line G connected with a switching unit 022, the touch IC 01 may be configured to: upon the display scanning operation on all the gate lines G in any touch region of the plurality of touch regions is completed, apply a touch scanning signal to the touch line connected with the touch capacitors in the any touch region so as to perform a touch scanning operation on the touch capacitors C in the any touch region.

To sum up, according to the touch display panel provided by the embodiment of the present disclosure, each of the touch lines is connected in series with at least one switching unit and the at least one switching unit is connected with at least one gate line on the base substrate in one-to-one correspondence. Furthermore, the switching unit can be switched off when a display scanning operation is performed on the corresponding gate line connected thereto and can be switched on when the display scanning operation is not performed on the corresponding gate line connected thereto. After the display scanning operation on all the gate lines in any of the touch regions is completed, the switching units in this touch region are all switched on, and then the touch IC can apply a touch scanning signal to the touch line corresponding to the touch capacitor in this touch region so as to perform a touch scanning operation to this touch region. In this way, it's unnecessary to wait for the completion of the touch scanning operation performed on all the gate lines on the base substrate to perform the touch scanning operation, so as to achieve starting a touch scanning operation upon the display scanning operation having been completed in part of the touch regions, thereby increasing the touch scanning time duration and realizing better touch effect in a high resolution touch display panel.

By way of example, the switching unit 022 may include a P-type field effect transistor (PFET), the PFET is connected to the corresponding gate line G through a gate electrode of the PFET, and the PFET is connected in series with the corresponding touch line T through a source electrode and a drain electrode of the PFET. It should be explained that, a P-type transistor is capable of being switched on when the gate electrode is inputted with a low level and being switched off when the gate electrode is inputted with a high level. Furthermore, when the display scanning operation is performed on the gate line G, the gate line G is transmitted with high level; and when the display scanning operation is not performed on the gate line G, the gate line G is transmitted with low level. In this way, the switching unit 022 is capable of being switched on when the display scanning operation is not performed on the corresponding gate line G connected thereto and being switched off when the display scanning operation is performed on the corresponding gate line G connected thereto.

The touch display panel provided by the embodiment of the present disclosure may be a mutual-capacitive touch display panel or a self-capacitive touch display panel which will be described as below by way of example.

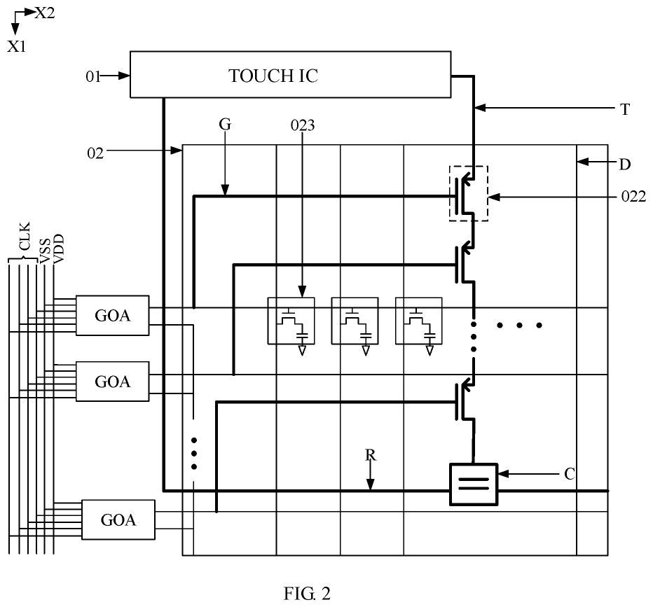

FIG. 2 is a schematic diagram illustrating a structure of a part of any touch region in a touch display panel provided by an embodiment of the present disclosure, and the touch display panel is a self-capacitive touch display panel.

As illustrated in FIG. 2, the self-capacitive touch display panel provided by an embodiment of the present discourse includes a touch IC 01 and a base substrate 02. The base substrate 02 may be provided with: m data lines D, n gate lines G, a plurality of pixel units 023, a plurality of touch lines T, at least one sense line R, and at least one row of touch capacitors C, n gate driver on array (GOA) units, a Voltage Drain Drain (VDD) terminal, a Voltage Series Series (VSS) terminal, and a Clock (CLK) terminal. Each of m and n is an integer equal to or greater than 1, and a value of m may be equal to or different from a value of n, without particularly limited in the embodiment of the present disclosure.

In the present embodiment, the data lines D and the gate lines G may be arranged to be intersected with each other; each of the pixel units 023 is connected with one of the gate lines G and one of the data lines D; n GOA units are connected with n gate lines in one-to-one correspondence, and each of the GOA units is connected with all of the VDD terminal, VSS terminal and CLK terminal; the n GOA units are cascaded to constitute one GOA. The touch lines T and the sense lines R are arranged to be intersected with each other, the touch line T may be parallel to the data line D and the sense line R may be parallel to the gate line G; one end of each of the touch capacitors C is connected with one touch line T and the other end of the touch capacitor is connected with one sense line R. The number of sense lines R disposed in each of the touch regions 021 may be as same as the number of rows of touch capacitors C in this touch region 021.

By way of example, each of the touch regions 021 may be provided with one sense line R, and a portion of each of the touch lines T located in each of the touch regions 021 is connected in series with at least one switching unit 022. FIG. 2 illustrates the case where a portion of each of the touch lines T located in each of the touch regions 021 is connected in series with n switching units, but the embodiment of the present disclosure is not limited thereto. The at least one switching unit 022 may be connected with the gate lines in the touch region in one-to-one correspondence. Moreover, in each of the touch regions 021, the switching unit 022 may be located between the touch IC 01 and the touch capacitor C.

In the touch display panel provided by the present embodiment, the touch IC 01 may be configured to sense a touch scanning signal through the sense line R in any of the touch regions when the touch line connected to the touch capacitor in this touch region is applied with the touch scanning signal, so as to perform the touch scanning operation on the touch capacitor C in this touch region.

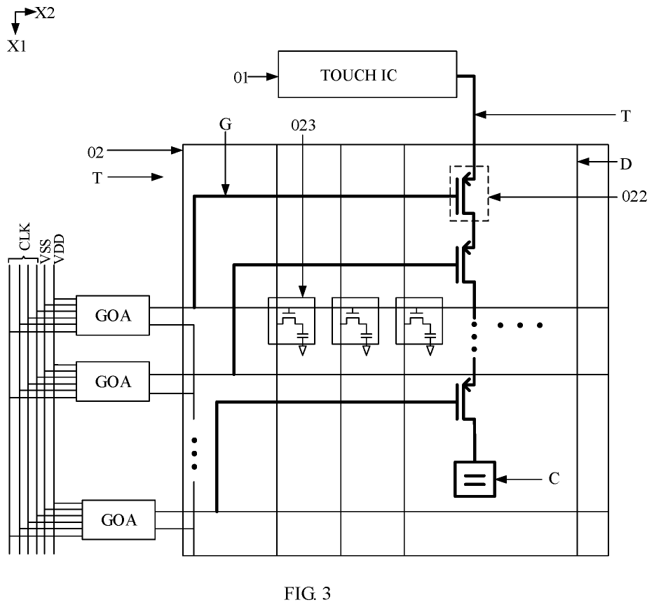

FIG. 3 is a schematic diagram illustrating a structure of a part of any touch region in another touch display panel provided by an embodiment of the present disclosure, and the touch display panel is a self-capacitive touch display panel. The self-capacitive touch display panel is different from the mutual-capacitive touch display panel in that, the self-capacitive touch display panel is not provided with any sense line.

As illustrated in FIG. 3, the self-capacitive touch display panel provided by an embodiment of the present disclosure includes a touch IC 01 and a base substrate 02. The base substrate 02 of the self-capacitive touch display panel may be provided with a plurality of touch lines T, and the plurality of touch lines T are connected with the plurality of touch capacitors C of the touch display panel in one-to-one correspondence. Each of the touch lines T is connected in series with at least one switching unit 022.

Optionally, the at least one switching unit 022 connected in series with each of the touch lines T may be located in a same touch region and may be connected with the gate lines G in the same touch region in one-to-one correspondence.

In the touch display panel, the touch IC 01 may be configured to apply a touch scanning signal to the touch line T connected with the touch capacitor C in any touch region 021 of the plurality of touch regions 021 upon the display scanning operation on all the gate lines G in this touch region 021 being completed, and to sense the touch scanning signal through the touch line T so as to perform the touch scanning operation on the touch capacitor C in this touch region 021.

In the touch display panel (e.g., the touch display panel illustrated in FIGS. 1-3) provided by the embodiments of the present disclosure, the base substrate 02 may also have a first region Q1, and each of the touch regions 021 may include a second region Q2 and a third region Q3. Hereinafter, embodiments of the first region Q1, the second region Q2 and the third region Q3 will be described by way of example.

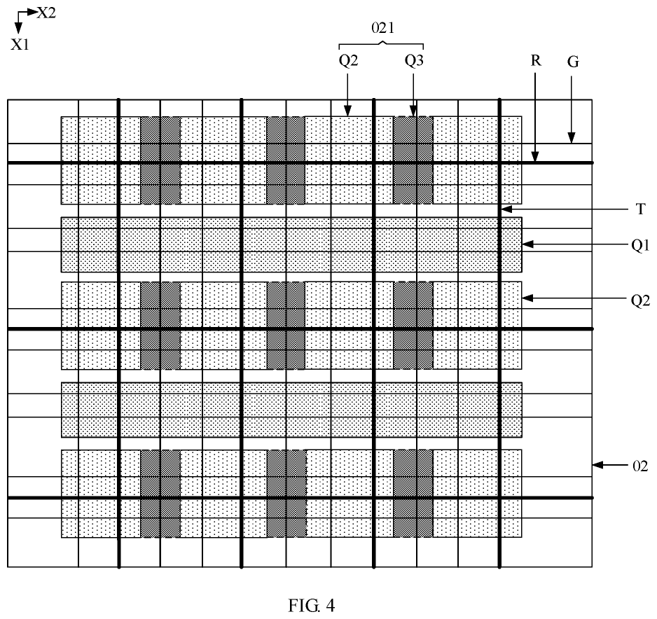

By way of example, FIG. 4 is a schematic diagram illustrating a structure of another touch display panel provided by an embodiment of the present disclosure. As illustrated in FIG. 4, the base substrate 02 is provided with at least one first region Q1 arranged along the X1 direction sequentially.

By way of example, the first region Q1 may be located between adjacent two control regions 021, and each first region Q1 may be provided with at least one gate line G FIG. 4 illustrates the case where the first region Q1 is provided with two gate lines G but the embodiment of the present disclosure is not limited thereto. Optionally, the number of gate line G disposed in the first region Q1 may be other values, e.g., one, which is not particularly limited in the embodiment of the present disclosure.

It should be explained that, a length of the first region Q1 along the X1 direction is required to be smaller than a minimum touch area, and the minimum touch area is a minimum contact area between a finger of a user and the touch display panel when the user touches the touch display panel with the finger. By way of example, when the touch display panel has a display region of 10.1 inches, the length of the first region in the X1 direction may be 0.1 mm

Moreover, in the present embodiment, the first region Q1 is neither provided with the touch capacitor C nor the sense line R. Because the first region Q1 is located between adjacent touch regions 012 and the first region Q1 is not provided with the sense line R, the first region Q1 can prevent from any touch interference between two sense lines adjacent to the first region Ql.

Optionally, there is one first region Q1 between any two adjacent touch regions 021. Because the first region Q1 is provided between every two adjacent touch regions 021, the first region Q1 can also prevent from any touch interference between sense lines R in any two touch regions 021.

By way of example, still referring to FIG. 4, each of the touch regions 021 on the base substrate 02 includes a plurality of second regions Q2 and at least one third region Q3. Furthermore, the plurality of second regions Q2 may be arranged sequentially along the X2 direction, and the third region Q3 is located between adjacent two second regions Q2; both of the second region Q2 and the third region Q3 are provided with at least one data line D, the second region Q2 is provided with at least one sense line T, and the third region Q3 is not provided with the touch line T. Because the third region Q3 is disposed between adjacent second regions Q2 and is not provided with the touch line T, it can prevent from any touch interference between two touch lines T adjacent to the third region Q3.

Optionally, there is one third region Q3 between any two adjacent second regions Q2. Because the third region Q3 is disposed between every two adjacent second regions Q2, it can further prevent from any touch interference between touch lines T in any two second regions Q2.

It should be explained that, FIG. 4 illustrates the case where the second region Q2 is provided with one data line D and one touch line T and the third region Q3 is provided with one data line D, but the embodiment of the present disclosure is not limited thereto. For example, the number of the data line D and the touch line T disposed in the second region Q2 may be other values, e.g., the second region may be provided with a plurality of data lines D and a plurality of touch lines T, which is not particularly limited in the embodiment of the present disclosure.

It should also be explained that, a length of the third region Q3 along the X2 direction is required to be smaller than the minimum touch area. By way of example, when the touch display panel has a display region of 10.1 inches, the length of the third region Q3 in the X2 direction may be 0.1 mm Optionally, the touch display panel may have a display region with other sizes (e.g., 5 inches or the like) and the length of the third region Q3 in the X2 direction may have other values, e.g., 0.2 mm or the like, which is not particularly limited in the embodiment of the present disclosure.

FIG. 5 is a schematic diagram illustrating a touch scanning operation and a display scanning operation of a touch display panel in the related art. As illustrated in FIG. 5, during an operation of the touch display panel, it needs to periodically perform touch display scanning By way of example, during every touch display scanning period T, the touch display panel usually performs a display scanning operation and a touch scanning operation sequentially. For example, given that the time duration of display scanning operation for the entire touch display panel is t1 and that the time duration of touch scanning operation for the entire touch display panel is t2, then the time duration tl of display scanning operation is apparently greater than the time duration t2 of touch scanning operation, within one touch display scanning period T, as can be seen from FIG. 5.

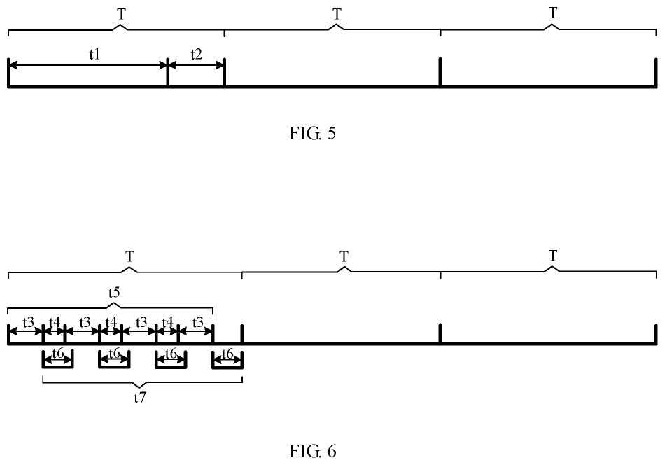

FIG. 6 is a schematic diagram illustrating a touch scanning operation and a display scanning operation of a touch display panel provided by an embodiment of the present disclosure. As illustrated in FIG. 6, given that the touch display scanning period of the touch display panel is also T, the time duration of display scanning operation for every touch region 021 may be t3, and the time duration of display scanning operation for every first region Q1 may be t4; thus, the time duration t5 of display scanning operation for the entire touch display panel may be a total sum of time durations of display scanning operation for all the touch regions and all the first regions in the touch display panel. After the display scanning operation for all the gate lines G in every touch regions 021 is completed, all the switching units 022 in this touch region 021 are switched on; at this time, the touch IC 01 can apply the corresponding touch line T with a touch scanning signal and perform touch scanning operation on the touch capacitor C in this touch region; the time duration of touch scanning operation in this touch region may be t6 (the time duration of touch scanning operation in this touch region may not be t6, for example, it may be greater than t6 or smaller than t6); therefore, the time duration from the point of starting the touch scanning operation to the point of finishing the touch scanning may be T-t3, that is, t7 illustrated in FIG. 6.

As it can be seen from FIG. 6, the time duration t5 of display scanning operation for the touch display panel provided by the embodiment of the present disclosure is greater than the time duration tl of display scanning operation in the related art, the time duration (e.g., four times of t6 as illustrated in FIG. 6) of touch scanning operation for the touch display panel provided by the embodiment of the present disclosure is also greater than the time duration t2 of touch scanning operation in the related art, and the touch display panel can be a touch display panel with high resolution. Moreover, the touch display panel provided by the embodiment of the present disclosure can start the touch scanning operation just after the completion of the display scanning operation in part of the touch regions, which increases the time duration of touch scanning operation and achieves better touch effect in the touch display panel with higher resolution.

By way of example, the touch display panel provided by the embodiment of the present disclosure (e.g., the touch display panel illustrated in FIG. 1-FIG. 3) may be a built-in touch display panel, an on-cell touch display panel, an integrated touch display panel or the like, which is not particularly limited in the embodiment of the present disclosure. The touch display panel provided by the embodiment of the present disclosure may also be a liquid crystal touch display panel, an organic light-emitting diode (OLED) touch display panel, an active matrix organic light-emitting diode (AMOLED) touch display panel or the like, which is not particularly limited in the embodiment of the present disclosure, either. Furthermore, the above-described touch display panel provided by the embodiment of the present disclosure may also possess the function of lighting a switched-off screen; that is, when the touch display panel does not display an image, the touch IC in the touch display panel may control the touch display panel to display an image upon the user touching the touch display panel.

Based on an inventive concept as same as that of the touch display panel provided by the foregoing embodiments of the present disclosure, an embodiment of the present disclosure further provides a display device including the touch display panel described in any of the foregoing embodiments. By way of example, the display device may be any product or component having the function of touch display, such as a mobile phone, a tablet computer and a notebook computer.

The above are only optional embodiments of the present disclosure without limiting the present disclosure. Any modifications, equivalent substitutions, improvements or the like within the spirit and principle of the present disclosure should be fallen within the protection scope of the present disclosure. Therefore, the protection scope of the present disclosure should be delimited by the protection scope of the claims.

1. A touch display panel, comprising: a touch integrated circuit (IC) and a base substrate, wherein
the base substrate is provided with data lines extending in a X1 direction, gate lines extending in a X2 direction intersected with the X1 direction, at least one touch line, and a plurality of touch capacitors, the plurality of touch capacitors are arranged in the X2 direction as a row direction and arranged in the X ldireciton as a column direction, each of the plurality of touch capacitors is connected with one of the at least one touch line, and the touch IC is connected with each of the at least one touch line,
the base substrate has a plurality of touch regions arranged along the X1 direction sequentially, each of the plurality of touch regions is provided with at least one gate line and at least one row of touch capacitors,
each of the at least one couch line is connected in series with at least one switching unit, and the at least one switching unit is connected with at least one gate line on the base substrate in one-to-one correspondence;
the switching unit is configured to be switched off in the case where a display scanning operation is performed on a corresponding gate line connected to the switching unit, and to be switched on in the case where the display scanning operation is not performed on the corresponding gate line connected to the switching unit; and
the touch IC is configured to apply a touch scanning signal to the touch line connected to the at least one row of touch capacitors in any touch region of the plurality of touch regions upon the display scanning operation on the at least one gate line in the any touch region being completed, so as to perform a touch scanning operation on the at least one row of touch capacitors in the any touch region.

2. The touch display panel according to claim 1, wherein the switching unit comprises a P-type field effect transistor (PFET),
the PFET is connected to the corresponding gate line through a gate electrode of the PFET, and
the PFET is connected in series with the corresponding touch line through a source electrode and a drain electrode of the PFET.

3. The touch display panel according to claim 1, wherein the base substrate is further provided with at least one sense line arranged to be intersected with the at least one touch line, the touch line is parallel to the data line, and the sense line is parallel to the gate line,
each of the at least one touch line is connected with one end of one corresponding touch capacitor on the base substrate, each of the at least one sense line is connected with the other end of the one corresponding touch capacitor on the base substrate;
each of the plurality of touch regions is provided with one sense line, and a portion of each of the at least one sense line located in each of the plurality of touch regions is connected in series with at least one switching unit, and the at least one switching unit is connected with the at least one gate line in each of the plurality of touch regions in one-to-one correspondence; and
the touch IC is configured to, upon the display scanning operation performed on the at least one gate line in any touch region of the plurality of touch regions being completed, when a touch scanning signal is applied to the touch line connected to the at least one row of touch capacitors in the any touch region, sense the touch scanning signal through the sense line in the any touch region so as to perform a touch scanning operation on the at least one row of touch capacitors in the any touch region.

4. The touch display panel according to claim 1, wherein,
in any of the plurality of touch regions, the at least one switching unit is located between the touch IC and the at least one row of touch capacitors.

5. The touch display panel according to claim 1, wherein the at least one touch line is connected with the plurality of touch capacitors in one-to-one correspondence, and
the at least one switching unit connected in series with each of the at least one touch line is located in a same touch region and is connected with the at least one gate line in the same touch region in one-to-one correspondence.

6. The touch display panel according to claim 1, wherein the base substrate further has at least one first region arranged along the X1 direction sequentially,
the first region is located between adjacent two touch regions, and
the first region is provided with at least one gate line and is not provided with the touch capacitor.

7. The touch display panel according to claim 6, wherein between any two adjacent touch regions, one first region is provided.

8. The touch display panel according to claim 1, wherein
each of the plurality of touch regions comprises: a plurality of second regions and at least one third region,
in each of the plurality of touch regions, the plurality of second regions are arranged along the X2 direction sequentially, and the third region is located between adjacent two second regions; and
both of the second region and the third region are provided with at least one data line, the second region is provided with at least one touch line, and the third region is not provided with the touch line.

9. The touch display panel according to claim 8, wherein between any two adjacent second regions, one third region is provided.

10. The touch display panel according to claim 1, wherein the base substrate is further provided with a plurality of gate driver on array (GOA) units connected with the gate lines in one-to-one correspondence,
the plurality of GOA units are cascaded to constitute a GOA.

11. The touch display panel according to claim 1, wherein the touch display panel is a built-in touch display panel, an on-cell touch display panel or an integrated touch display panel.

12. The touch display panel according to claim 1, wherein the touch display panel is a liquid crystal touch display panel, an organic light-emitting diode (OLED) touch display panel or an active matrix organic light-emitting diode (AMOLED) touch display panel.

13. The touch display panel according to claim 6, wherein the touch display panel has a display region of 10.1 inches, and
a length of each of the at least one first region in the X1 direction is 0.1 mm.

14. A display device comprising the touch display panel according to claim 1.

15. The touch display panel according to claim 3, wherein the base substrate further has at least one first region arranged along the X1 direction sequentially,
the first region is located between adjacent two touch regions, and
the first region is provided with at least one gate line and is not provided with the touch capacitor.

16. The touch display panel according to claim 15, wherein between any two adjacent touch regions, one first region is provided.

17. The touch display panel according to claim 3, wherein
each of the plurality of touch regions comprises: a plurality of second regions and at least one third region,
in each of the plurality of touch regions, the plurality of second regions are arranged along the X2 direction sequentially, and the third region is located between adjacent two second regions; and
both of the second region and the third region are provided with at least one data line, the second region is provided with at least one touch line, and the third region is not provided with the touch line.

18. The touch display panel according to claim 17, wherein between any two adjacent second regions, one third region is provided.

19. The display device according to claim 14, wherein the base substrate is further provided with at least one sense line arranged to be intersected with the at least one touch line, the touch line is parallel to the data line, and the sense line is parallel to the gate line,
each of the at least one touch line is connected with one end of one corresponding touch capacitor on the base substrate, each of the at least one sense line is connected with the other end of the one corresponding touch capacitor on the base substrate;
each of the plurality of touch regions is provided with one sense line, and a portion of each of the at least one sense line located in each of the plurality of touch regions is connected in series with at least one switching unit, and the at least one switching unit is connected with the at least one gate line in each of the plurality of touch regions in one-to-one correspondence; and
the touch IC is configured to, upon the display scanning operation performed on the at least one gate line in any touch region of the plurality of touch regions being completed, when a touch scanning signal is applied to the touch line connected to the at least one row of touch capacitors in the any touch region, sense the touch scanning signal through the sense line in the any touch region so as to perform a touch scanning operation on the at least one row of touch capacitors in the any touch region.

20. The display device according to claim 14, wherein,
in any of the plurality of touch regions, the at least one switching unit is located between the touch IC and the at least one row of touch capacitors.
